(19) United States
(12) Patent Application Publication
(10) Pub. No.: US 2026/0324317 A1
(43) Pub. Date: Oct. 15, 2026

(54) METHODS TO CONTROL DELTA BOW OF 3D NAND ONON STACK

(71) Applicant: Applied Materials, Inc., Santa Clara, CA (US)

(72) Inventors: Allison YAU, Cupertino, CA (US); Zhiling DUN, Santa Clara, CA (US); Manoj Kumar JANA, San Jose, CA (US); Shichen FU, Santa Clara, CA (US); Hang YU, Woodland, CA (US)

(21) Appl. No.: 19/175,626

(22) Filed: Apr. 10, 2025

(51) Int. Cl. H01L 21/02; H10B 41/20; H10B 43/20

(52) U.S. Cl. CPC H10P 14/69215; H10P 14/6336; H10P 14/6529; H10P 14/69433; H10B 41/20; H10B 43/20

(57) ABSTRACT

Embodiments of the present disclosure relate to apparatuses and methods of manufacturing layer stacks of ON layers that reduce or prevent anneal-induced structural changes of an ON stack. In at least some embodiments, a method for forming an oxide/nitride (ON) stack is provided and includes depositing a first material layer including silicon nitride (SiN) and having a silicon-hydrogen bond (Si—H) content of about 0.35% or less, depositing a second material layer onto the first material layer, the second material layer including silicon oxide (SiO) and having a nitrogen content of about 0.01% to about 1.5%, and annealing the first material layer and the second material layer.

### BACKGROUND

### Field

The present disclosure generally relates to memory devices, and methods of manufacturing the same, and more particularly, to memory device structures and methods of forming the same.

### Description of the Related Art

Memory devices are an essential component in digital electronic devices that are being developed today. Growing demands drive the need for high-capacity, high performance computer memory devices with smaller geometries at lower costs. To this end, components of memory cells are stacked on top of each other to create three-dimensional (3D) memory cells, such as vertical gate 3D memory cells. One such technology is NAND flash memory (or a “3D NAND memory structure”), which is generally found in memory cards, Universal Serial Bus (USB) flash drives, solid-state drives, and other similar devices for data storage and transfer.

### SUMMARY

Embodiments of the present disclosure generally relate to device structures and methods of forming three-dimensional (3D) memory devices. More particularly, embodiments of the present disclosure relate to methods of manufacturing layer stacks of oxide/nitride (ON) layers that reduce or prevent anneal-induced structural changes of the ON stack.

In at least some embodiments, a method for forming an oxide/nitride (ON) stack is provided and includes depositing a first material layer including silicon nitride (SiN) and having a silicon-hydrogen bond (Si—H) content of about 0.35% or less, depositing a second material layer onto the first material layer, the second material layer including silicon oxide (SiO) and having a nitrogen content of about 0.01% to about 1.5%, and annealing the first material layer and the second material layer.

In at least some embodiments, a method for forming an ON stack is provided. The method includes depositing a first material layer including SiN, depositing a second material layer onto the first material layer, the second material layer including SiO, repeating depositing the first material layer and depositing the second material layer one or more times to form the ON stack, and annealing the ON stack. Depositing the first material layer includes, providing a silicon containing gas, one or more nitrogen containing gases, and a carrier gas into a process chamber, and operating the process chamber at a high frequency radio frequency (HFRF) power of about 1,500 W to about 2,500 and a low frequency RF (LFRF) power of about 0 W to about 1,000 W.

In at least some embodiments, a method for forming an ON stack is provided. The method includes depositing a first material layer including SiN, depositing a second material layer onto the first material layer, the second material layer including SiO, repeating depositing the first material layer and depositing the second material layer one or more times to form the ON stack, and annealing the ON stack. Depositing the second material layer includes, providing a silicon containing gas, oxygen (O₂), nitrogen (N₂), and a carrier gas into a process chamber, and operating the process chamber at a HFRF power of about 0 W to about 4,000 W and a LFRF power of about 0 W to about 1,000 W.

At least some embodiments provide an ON stack, comprising a first material layer including silicon nitride (SiN) and having a silicon-hydrogen bond (Si—H) content of about 0.35% or less, and a second material layer disposed over the first material layer, the second material layer including silicon oxide (SiO) and having a nitrogen content of about 0.01% to about 1.5%.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic view of an example 3D NAND memory structure according to some embodiments.

FIG. 2 a simplified schematic view of an ON stack according to some embodiments.

FIGS. 3 and 4 depict process flow diagrams of methods of forming an ON stack according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Vertical stacking in a 3D NAND memory structure is ever-increasing to meet the growing demand for memory capacity. Such 3D memory structures are sometimes referred to as having a Bit Cost Scalable (BiCS) architecture, and include strings of vertically integrated memory cells. Typically, the vertically aligned memory cells are formed from an array of alternating conductor and insulator layers, where the conductive layers correspond to the word lines of the memory structure. High-aspect-ratio holes etched down through hundreds of Oxide/Nitride (ON) stacks form the memory core of a 3D NAND memory structure. In some instances, the ON stacks may be formed from layers of Silicon oxide (SiO) and Silicon nitride (SiN). SiN is the sacrificial layer that is replaced with metal to form the word lines. High temperature thermal annealing is used to produce the physical and electrical properties that allow 3D NAND devices to function correctly and reliably. Anneal-induced structural changes (e.g., bowing and shrinking) of the ON stack pose downstream integration challenges by distorting the memory holes.

Therefore, there is a need for methods of manufacturing layer stacks of ON layers that reduce or prevent anneal-induced structural changes.

Accordingly, embodiments disclosed herein generally relate to device structures and methods of forming three-dimensional (3D) memory devices. More particularly, some embodiments of the present disclosure relate to methods of manufacturing layer stacks of ON layers that reduce or prevent anneal-induced structural changes of an ON stack. It has been discovered that post anneal substrate bowing may be reduced or prevented by tuning the hydrogen (H) content, nitrogen (N) content, and as-deposited stress and elemental composition of SiO layers and SiN layers of an ON stack.

In at least some embodiments, a high SiN layer deposition rate of about 5,000 Angstroms per minute (A/min), may be achieved while maintaining a low post thermal anneal delta (Δ) stress of about 40 Megapascals (MPa) to about 60 MPa, a low shrinkage, an as deposited stress of about 400 Mpa or less, and a Reflective index (RI) of about 1.9 or greater when measured at 248 nm, through a balance of depositions conditions including high pressure, substrate spacing, and gas flows/ratios. In at least some embodiments, a high temperature deposition method provides a SiN layer having a low silicon-bound hydrogen (Si—H) content. In at least some embodiments, a high frequency Radio Frequency (HFRF) deposition method provides a SiN layer having a low Si—H content of about 0.35% or less and a post anneal Δ stress of about 20 MPa to about 50 MPa. In at least some embodiments, the methods disclosed herein provide a SiO layer having a nitrogen content of about 0.01% to about 1.5%. In at least some embodiments, the methods disclosed herein provide an ON stack having a post anneal Δ bow of about −10 micrometer (μm) to about 20 μm.

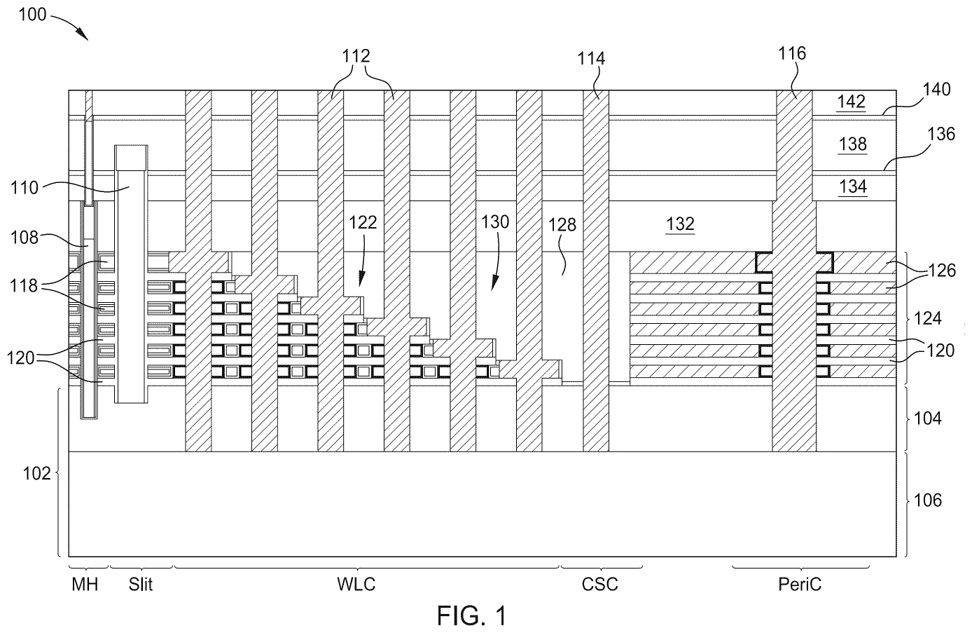

FIG. 1 is a schematic view of an example 3D NAND memory structure 100. The 3D NAND memory structure 100 is formed on a substrate 102 that includes a common source line (CSL) layer 104 and a complementary metal-oxide semiconductor (CMOS) circuit layer 106 formed therewithin. The 3D NAND memory structure 100 includes a memory hole (MH) region, in which memory holes 108 are formed, a slit region in which a gate slit line 110 is formed, a word line contact (WLC) region in which word line contacts 112 are formed, a common source contact (CSC) region in which a common source contact 114 is formed, and a peripheral contact (PeriC) region in which peripheral contacts 116 are formed. The 3D NAND memory structure 100 includes a stack of alternating word line layers 118 and oxide layers 120 in the direction perpendicular to the major surface of the substrate 102 to form a string of memory cells. An end of the stack of the word line layers 118 and the oxide layer 120 forms a staircase 122, such that each of the word line layers 118 can be connected to one of the word line contacts 112. In this way, in the 3D NAND memory structure 100, memory cells may be fabricated in a vertical direction along the memory hole 108, so that a memory capacity may be easily increased by stacking additional word line layers 118. The 3D NAND memory structure 100 further includes a stacking mold 124 of alternating oxide layers 120 and nitride layers 126 formed on the substrate 102. The word line layers 118 are formed by removing the nitride layers 126 in the stacking mold 124 in the MH region, the slit region, and the WLC region, and then depositing a metal layer in the same place where the nitride layers 126 were removed.

The 3D NAND memory structure 100 further includes an insulator layer 128 filling an opening 130 adjacent to the staircase 122, an inter-layer dielectric (ILD) layer 132 over the stack of the word line layers and the oxide layer 120, the insulator layer 128, and the stacking mold 124, a dielectric layer 134 over the ILD layer 132, a dielectric layer 136 over the dielectric layer 134, a dielectric layer 138 over the dielectric layer 136, a dielectric layer 140 over the dielectric layer 138, and a dielectric layer 142 over the dielectric layer 140. The dielectric layers 134, 138, and 142 may be formed of silicon oxide (SiO₂). The dielectric layers 136 and 140 may be formed of silicon nitride (Si₃N₄) and act as chemical mechanical planarization (CMP) stop layers.

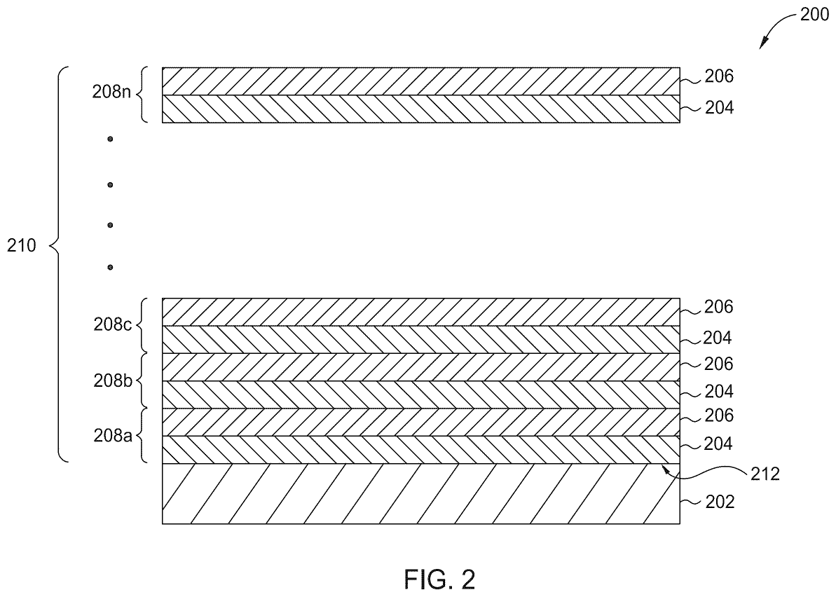

FIG. 2 is a simplified schematic cross-sectional view of an ON stack 200 according to embodiments of the present disclosure. The ON stack 200 includes a substrate 202 with a plurality of first material layers 204 and a plurality of second material layers 206 disposed thereon. Material layer pairs 208a, 208b, 208c, . . . 208n, also known as a plurality of material layer pairs 208 of a first material layer of the plurality of first material layers 204 and a second material layer of the plurality of second material layers 206, make up a layer stack 210. In at least some embodiments, each of the first material layers 204 is a SiN layer and each of the second material layers 206 is a SiO layer. While FIG. 2 depicts the second material layer 206 deposited over the first material layer 204, the deposition order may be reversed such that the first material layer 204 (SiN layer) is deposited over the second material layer 206 (SiO layer). In an embodiment in which the ON stack 200 is a portion of a memory device, such as the 3D NAND memory structure 100, the ON stack 200 further includes a source and a drain (not shown) disposed on opposite ends of a first surface 212 of the substrate 202. For use as flash memory, multiple NAND flash cells are generally connected in series with the adjacent cells sharing a source or drain, and each cell is connected to a bitline and a wordline. In operation, each cell can store data, such as a “0” or “1,” therein.

In at least some embodiments, the first material layer 204 is a SiN layer. In at least some embodiments, the SiN first material layer 204 may have a refractive index (RI) at 248 nm of about 1.5 to about 2.0, such as about 1.6 to about 1.95, about 1.8 to about 1.95, about 1.9 to about 1.95, about 1.5 to about 1.9, or about 1.5 to about 1.88. The SiN first material layer 204 may have a thickness of about 200 Angstroms (A) to about 2,250 A, such as about 200 A to about 1,000 A, about 200 A to about 500 A, about 200 A to about 300 A, about 500 A to about 2,250 A, about 1,000 A to about 2,250 A, about 1,500 A to about 2,250 A, about 1,800 A to about 2,250 A, about 1,900 A to about 2,250 A, about 2,000 A to about 2,250 A. In at least some embodiments, the SiN first material layer 204 may have an as deposited stress, such as a tensile stress, of about 300 MPa or greater, such as about 300 MPa to about 500 MPa, about 300 MPa to about 450 MPa, or about 300 MPa to about 400 MPa. In at least some embodiments, the SiN first material layer 204 may have an as deposited Si—H content of about 0.35% or less, such as about 0% to about 0.35%, about 0.0% to about 0.3%, about 0.01% to about 0.3%, or about 0.1% to about 0.3%. The SiN first material layer 204 may have an as deposited N—H content of about 6% to about 10%, such as about 6% to about 9%, about 7% to about 9%, about 6% to about 8%, about 6% to about 7.5%, or about 5% to about 10%. The SiN first material layer 204 may have an as deposited H content of about 10% to about 20%, such as about 12.5% to about 20%, about 10% to about 15%, about 15% to about 20%, about 18% to about 20%, or about 15% to about 18%. The SiN first material layer 204 may have an as deposited N content of about 40% to about 60%, such as about 40% to about 55%, about 45% to about 55%, about 45% to about 50%, or about 50% to about 60%.

In at least some embodiments, the SiN first material layer 204 may have a post anneal Δ stress of about −70 MPa to about 160 MPa, such as about −30 MPa to about 150 MPa, about −20 MPa to about 120 MPa, about 0 MPa to about 100 MPa, about −20 MPa to about 50 MPa, about 0 MPa to about 50 MPa, about 50 MPa to about 150 MPa, −20 MPa to about 100 MPa, or about −15 MPa to about 80 MPa. In at least some embodiments, the SiN first material layer 204 may have a post anneal Si—H content of about 0.01% to about 0.1%, such as about 0.02% to about 0.1%, about 0.03% to about 0.07%, or about 0.03% to about 0.05%. The SiN first material layer 204 may have a post anneal N—H content of about 5% to about 10%, such as about 6% to about 10%, about 6% to about 8%, or about 6% to about 7%. The SiN first material layer 204 may have a post anneal H content of about 10% to about 20%, such as about 12.5% to about 20%, about 10% to about 15%, about 15% to about 20%, about 18% to about 20%, or about 15% to about 18%. In at least some embodiments, the post anneal H content of SiN first material layer 204 may be about 1% to about 2% less than the as deposited H content of SiN first material layer 204. The SiN first material layer 204 may have a post anneal N content of about 40% to about 60%, such as about 40% to about 55%, about 45% to about 55%, about 45% to about 50%, or about 50% to about 60%. In at least some embodiments, the N content of SiN first material layer 204 may not change post anneal. For example, in at least some embodiments, a SiN first material layer 204 having an as deposited stress of about 380 MPa to about 450 MPa and an RI of about 1.9 to about 2 has a post anneal Δ stress of about 20 MPa to about 160 MPa. In at least some embodiments, a SiN first material layer 204 having an as deposited stress of about 395 MPa to about 430 MPa and an RI of about 1.9 to about 2 has a post anneal Δ stress of about 20 MPa to about 50 MPa. In at least some other embodiments, a SiN first material layer 204 having an as deposited stress of about 400 MPa to about 450 MPa and an RI of about 1.6 to about 1.88 has a post anneal Δ stress of about −25 MPa to about −10 MPa.

In at least some embodiments, the second material layer 206 is a SiO layer. In at least some embodiments, the SiO second material layer 206 may have a refractive index (RI) of about 1.4 to about 1.8, such as about 1.4 to about 1.7, about 1.4 to about 1.6, or about 1.4 to about 1.5. The SiO second material layer 206 may have a thickness of about 100 A to about 1,000 A, such as about 200 A to about 1,000 A, about 100 A to about 500 A, about 100 A to about 300 A, about 100 A to about 200 A. In at least some embodiments, SiO second material layer 206 may have an as deposited stress, such as a compressive stress, of about of about −300 MPa or greater, such as about −300 MPa to about −500 MPa, about −300 MPa to about −450 MPa, or about −300 MPa to about −400 MPa. The SiO second material layer 206 may have an as deposited H content of about 0.1% to about 1%, such as about 0.2% to about 0.9%, about 0.4% to about 0.8%, about 0.1% to about 0.5%, or about 0.5% to about 0.8%. The SiO second material layer 206 may have an as deposited N content of about 0% to about 0.005%, such as about 0% to about 0.002%, or about 0% to about 0.001%. In at least some embodiments, the SiO second material layer 206 may have a post anneal Δ stress of about 20 MPa to about 60 MPa, such as about 20 MPa to about 40 MPa, or about 25 MPa to about 35 MPa. For example, in at least some embodiments, a SiO second material layer 206 having an as deposited stress of about −350 MPa to about −380 MPa, an as deposited N content of about 0% to about 0.002%, and a RI of about 1.2 to about 1.5 has a post anneal Δ stress of about 20 MPa to about 40 MPa.

In at least some embodiments, the ON stack 200 includes about 100 or more material layer pairs 208 of the SiN first material layer 204 and the SiO second material layer 206, such as about 100 to about 200 pairs. In such embodiments, the ON stack 200 may have an as deposited wafer/substrate bow of about −50 μm to about 50 μm, such as about −40 μm to about 40 μm, about −20 μm to about 50 μm, about −20 μm to about 10 μm, 5 μm to about 40 μm, about 10 μm to about 40 μm, about 5 μm to about 30 μm, or about 5 μm to about 20 μm. The ON stack 200 may have a post anneal Δ bow of about −20 μm to about 50 μm, such as about −20 μm to about 45 μm, about −10 μm to about 50 μm, about 10 μm to about 45 μm, or about 30 μm to about 40 μm. The SiO second material layer 206 of the ON stack 200 may have a post anneal H content of about 0.1% to about 1%, such as about 0.2% to about 0.9%, about 0.4% to about 0.8%, about 0.1% to about 0.5%, or about 0.5% to about 0.8%, a post anneal Oxygen content of about 50% to about 70%, such as about 55% to about 65%, or about 60% to about 70%, and a post anneal N content of about 0.1% to about 1%, such as about 0.2% to about 0.9%, about 0.4% to about 0.8%, about 0.1% to about 0.5%, or about 0.5% to about 0.8%. The SiN first material layer 204 of the ON stack 200 may have a post anneal H content of about 10% to about 20%, such as about 12.5% to about 20%, about 10% to about 15%, about 15% to about 20%, about 18% to about 20%, or about 15% to about 18%, a post anneal Oxygen content of about 0.01% to about 0.1%, such as about 0.02% to about 0.1%, about 0.03% to about 0.07%, or about 0.03% to about 0.05%, and a post anneal N content of about 40% to about 60%, such as about 40% to about 55%, about 45% to about 55%, about 45% to about 50%, or about 50% to about 60%.

In at least some embodiments, the second material layer 206 is a SiO layer doped with nitrogen to increase the N content and decrease the H content of the layer. In at least some embodiments, the N doped SiO second material layer 206 may have a refractive index (RI) of about 1.4 to about 1.8, such as about 1.4 to about 1.7, about 1.4 to about 1.6, or about 1.4 to about 1.5. The N doped SiO second material layer 206 may have a thickness of about 100 A to about 1,000 A, such as about 200 A to about 1,000A, about 100 A to about 500 A, about 100 A to about 300 A, about 100 A to about 200 A. In at least some embodiments, the N doped SiO second material layer 206 may have an as deposited stress, such as a compressive stress, of about about −300 MPa or greater, such as about −300 MPa to about −500 MPa, about −300 MPa to about −450 MPa, or about −300 MPa to about −400 MPa. The N doped SiO second material layer 206 may have an as deposited H content of about 0.01% to about 0.5%, such as about 0.1% to about 0.5%, about 0.1% to about 0.4%, or about 0.2% to about 0.4%. The N doped SiO second material layer 206 may have an as deposited N content of about 0.01% to about 1.5%, such as about 0.1% to about 1.0%, about 0.1% to about 0.5%, about 0.1% to about 0.4%, or about 0.2% to about 0.4%. In at least some embodiments, the N doped SiO second material layer 206 may have a post anneal Δ stress of about 40 MPa to about 60 MPa, such as about 40 MPa to about 55 MPa, about 45 MPa to about 55 MPa, or about 20 MPa to about 50 MPa. For example, in at least some embodiments, a N doped SiO second material layer 206 having an as deposited stress of about −350 MPa to about −380 MPa, an as deposited N content of about 0.05% to about 0.2%, and a RI of about 1.2 to about 1.5 has a post anneal Δ stress of about 40 MPa to about 55 MPa.

In at least some other embodiments, the ON stack 200 includes about 100 or more material layer pairs 208 of the SiN first material layer 204 and the N doped SiO second material layer 206 such as about 100 to about 200 pairs. In such embodiments, the ON stack 200 may have an as deposited wafer/substrate bow of about −50 μm to about 50 μm, such as about −40 μm to about 40 μm, about −20 μm to about 50 μm, about −20 μm to about 10 μm, 5 μm to about 40 μm, about 10 μm to about 40 μm, about 5 μm to about 30 μm, or about 5 μm to about 20 μm. The ON stack 200 may have a post anneal Δ bow of about −10 μm to about 60 μm, such as about −5 μm to about 50 μm, about 10 μm to about 40 μm, about 5 μm to about 40 μm, about 10 μm to about 30 μm, or about 5 μm to about 20 μm. In at least some embodiments, the ON stack 200 may have a post anneal Δ bow of about −10 μm to about 20 μm, such as about −5 μm to about 18 μm, about −5 μm to about 15 μm, or about 10 μm to about 20 μm. The N doped SiO second material layer 206 of the ON stack 200 may have a post anneal H content of about 0.1% to about 1%, such as about 0.2% to about 0.9%, about 0.4% to about 0.8%, about 0.1% to about 0.5%, or about 0.5% to about 0.8%, a post anneal Oxygen content of about 50% to about 70%, such as about 55% to about 65%, or about 60% to about 70%, and a post anneal N content of about 0.1% to about 1%, such as about 0.2% to about 0.9%, about 0.4% to about 0.8%, about 0.1% to about 0.5%, or about 0.5% to about 0.8%. The SiN first material layer 204 of the ON stack 200 may have a post anneal H content of about 10% to about 20%, such as about 12.5% to about 20%, about 10% to about 15%, about 15% to about 20%, about 18% to about 20%, or about 15% to about 18%, a post anneal Oxygen content of about 0.01% to about 0.5%, such as about 0.1% to about 0.5%, about 0.1% to about 0.4%, or about 0.2% to about 0.4%, and a post anneal N content of about 40% to about 60%, such as about 40% to about 55%, about 45% to about 55%, about 45% to about 50%, or about 50% to about 60%.

Doping the SiO second material layer 206 with nitrogen to increase the N content and decrease the H content of the layer increases the post anneal Δ stress of the individual SiO second material layer 206. For example, an SiO second material layer 206 having an as deposited N content of about 0.001% to about 0.01% has a post anneal Δ stress of about 20 MPa to about 40 MPa, whereas an N doped SiO second material layer 206 having an as deposited N content of about 0.01% to about 1.5% has a post anneal Δ stress of about 30 MPa to about 60 MPa. However, unexpectedly, the post anneal Δ bow is decreased when the SiO second material layer 206 is doped with nitrogen, even though the individual post anneal Δ stress increased. For example, an SiO second material layer 206 having an as deposited N content of about 0.001% to about 0.01% has a post anneal Δ bow of about 40 μm to about 55 μm, whereas an N doped SiO second material layer 206 having an as deposited N content of about 0.01% to about 1.5% has a post anneal Δ bow of about 12 μm to about 20 μm. Without being bound by theory, it is believed that in an ON stack the nitrogen element in the SiO second material layer 206 prevents loss of oxygen in the SiO layer and/or prevents hydrogen transport out of the material, reducing bond rearrangements thus resulting in a low Δ bow, such as about 12 μm to about 20 μm.

In at least some embodiments, an ON stack 200 having an deposited bow of about 5 μm to about 10 μm includes material layer pairs 208 of a SiN first material layer 204 having an as deposited stress of about 350 MPa to about 400 MPa, an as deposited H content of about 5% to about 20%, and an as deposited N content of about 30% to about 50%, and a SiO second material layer 206 having an as deposited stress of about −350 MPa to about −400 MPa, an as deposited H content of about 0.5% to about 1.0%, and an as deposited N content of about 0.001% to about 0.01%. The individual SiN first material layer 204 may have a post anneal Δ stress of about 15 MPa to about 30 MPa. The individual SiO second material layer 206 may have a post anneal Δ stress of about 20 MPa to about 40 MPa. The ON stack 200 may have a post anneal Δ bow of about 40 μm to about 55 μm.

In at least some other embodiments, an ON stack 200 having an as deposited bow of about 25 μm to about 45 μm includes material layer pairs 208 of a SiN first material layer 204 having an as deposited stress of about 350 MPa to about 400 MPa, an as deposited H content of about 5% to about 20%, and an as deposited N content of about 30% to about 50%, and a N doped SiO second material layer 206 having an as deposited stress of about −350 MPa to about −400 MPa, an as deposited H content of about 0.1% to about 0.5%, and an as deposited N content of about 0.01% to about 0.1%. In at least some embodiments, the post anneal Δ bow of the ON stack may be reduced even when the Δ stress of the individual SiN first material layer 204 and N doped SiO second material layer 206 increase or worsen. The individual SiN first material layer 204 may have a post anneal Δ stress of about 20 MPa to about 30 MPa. The individual N doped SiO second material layer 206 may have a post anneal Δ stress of about 30 MPa to about 60 MPa. The ON stack 200 may have a post anneal Δ bow of about 12 μm to about 20 μm. The nitrogen in the SiO second material layer 206 prevents loss of oxygen in the SiO layer, resulting in a low Δ bow, such as about 12 μm to about 20 μm.

In at least some embodiments, the Δ stress of the SiN first material layer 204 increases with an increase in RI while the Δ bow of the ON stack 200 decreases. As RI increases, the Si—H content in SiN layers remains the same while the N—H content decreases. When a SiN layer is incorporated into an ON stack as the SiN first material layer 204, the post anneal reduction of H content is not the same as that observed in a single layer of SiN. When annealed the reduction of both Si—H and N—H content is the same regardless of the RI of the SiN layer. In an ON stack hydrogen is more readily lost from the SiN layer due to the proximity of the SiO layer, which acts as a pump accelerating the diffusion of hydrogen in the SiN layer, the pump efficiency is higher with higher N—H content. As such, SiN layers having a lower N—H content and a higher RI lose less hydrogen during ON stack annealing than lower RI SiN layers, resulting in less bond rearrangement in the SiN layer and a lower Δ bow.

For example, in at least some embodiments, an ON stack 200 having an as deposited bow of about 25 μm to about 45 μm includes material layer pairs 208 of a SiN first material layer 204 having an as deposited stress of about 350 MPa to about 450 MPa, a N—H content of about 7% to about 9%, and a RI about 1.5 to about 1.88, and a N doped SiO second material layer 206 having an as deposited stress of about −350 MPa to about −400 MPa, an as deposited H content of about 0.1% to about 0.5%, and an as deposited N content of about 0.01% to about 0.1%. The individual SiN first material layer 204 has a post anneal Δ stress of about −15 MPa to about −30 MPa. The ON stack 200 has a post anneal Δ bow of about 40 μm to about 60 μm.

For example, in at least some other embodiments, an ON stack 200 having an as deposited bow of about −5 μm to about −20 μm includes material layer pairs 208 of a SiN first material layer 204 having an as deposited stress of about 350 MPa to about 425 MPa, a N—H content of about 6% to about 7.5%, and a RI about 1.9 to about 1.95, and a N doped SiO second material layer 206 having an as deposited stress of about −350 MPa to about −400 MPa, an as deposited H content of about 0.1% to about 0.5%, and an as deposited N content of about 0.01% to about 0.1%. The individual SiN first material layer 204 has a post anneal Δ stress of about 50 MPa to about 150 MPa. The ON stack 200 has a post anneal Δ bow of about −8 to about 15.

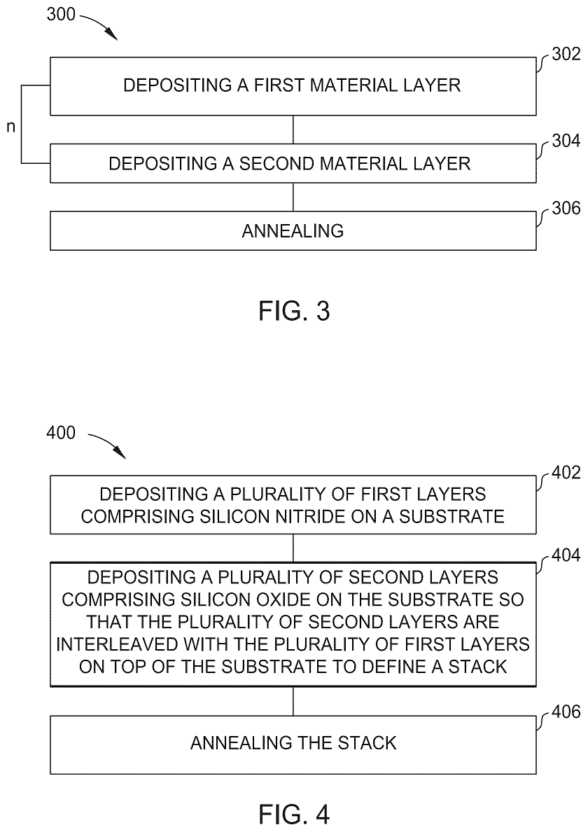

FIG. 3 depicts a process flow diagram of a method of forming an ON stack according to some embodiments. Method 300 may be carried out in any suitable process chamber or multiple process chambers. The method 300 generally includes depositing a first material layer at operation 302, depositing a second material layer at operation 304, repeating operations 302 and 304 n number of times to form a stack of material layer pairs of the first and second material layers, and annealing the deposited first and second material layers at operation 306.

Before operation 302 a substrate, such as substrate 202 is positioned in a process chamber. The substrate may be positioned on a pedestal within the process chamber. The pedestal may be configured to move to adjust the distance between the substrate and a showerhead before, after, and/or during operations 302 and 304.

At operation 302, a first material layer is deposited on a substrate. In at least some embodiments, the first material layer is a SiN layer, such as the first material layer 204. In at least some embodiments, depositing the SiN includes providing a silicon containing gas, one or more nitrogen containing gases, and a carrier gas into a process chamber, heating the pedestal to a temperature of about 400 degrees Celsius (° C.) to about 650° C. and operating the process chamber at a pressure of about 0 torr to about 20 torr, a high frequency radio frequency (HFRF) power of about 0 Watts (W) to about 4,000 W, and a low frequency RF (LFRF) power of about 0 W to about 1,000 W.

In at least some embodiments, the pedestal is heated to a temperature of about 400° C. to about 650° C., such as about 450° C. to about 650° C., about 500° C. to about 600° C., about 550° C. to about 600° C., or about 530° C. to about 550° C.. In at least some embodiments, the pedestal is heated to a temperature of about 550° C. or greater. In at least some embodiments, the spacing between the substrate and the showerhead is about 4.5 millimeters (mm) to about 20 mm, such as about 5 mm to about 20 mm, about 5 mm to about 15 mm, about 10 mm to about 20 mm, about 5 mm to about 10 mm, about 15 mm to about 20 mm, or about 14 mm to about 17 mm. In at least some embodiments, the process chamber is operated at a pressure of about 0 torr to about 20 torr, such as about 1 torr to about 20 torr, about 5 torr to about 20 torr, about 5 torr to about 15 torr, about 5 torr to about 10 torr, or about 6 torr to about 7.5 torr.

In at least some embodiments, the HFRF power may be about 0 W to about 4,000 W, such as about 10 W to about 4,000 W, about 50 W to about 4,000 W, about 100 W to about 4,000 W, about 500 W to about 4,000 W, about 1,000 W to about 4,000 W, about 1,000 W to about 3,500 W, about 1,000 W to about 3,000 W, about 1,500 W to about 3,000 W, about 1,800 W to about 2,500 W, or about 2,000 W to about 3,000 W. In at least some embodiments, the HFRF power is a high power, such as above about 1,500 W. In at least some embodiments, the LFRF power may be about 0 W to about 1,000 W, such as about 0 W to about 500 W, about 0 W to about 300 W, about 0 W to about 100 W about 10 W to about 1,000 W, about 50 W to about 1,000 W, about 50 W to about 500 W, about 80 W to about 300 W, about 100 W to about 1,000 W, about 500 W to about 1,000 W, about 800 W to about 1,000 W, or about 900 W to about 1,000 W.

In at least some embodiments, the silicon containing gas includes SiH₄ and SiH₄ is flowed into the process chamber at a flow rate of about 0 sccm to about 2,000 sccm, such as about 100 sccm to about 2000 sccm, about 500 sccm to about 2,000 sccm, about 1,000 sccm to about 1,900 sccm, about 1,400 sccm to about 1,900 sccm, or about 1,500 sccm to about 2,000 sccm. In at least some embodiments, the one or more nitrogen containing gases include NH₃ and NH₃ is flowed into the process chamber at a flow rate of about 0 sccm to about 35,000 sccm, such as about 100 sccm to about 30,000 sccm, about 500 sccm to about 25,000 sccm, about 1,000 sccm to about 20,000 sccm, about 2,000 sccm to about 15,000 sccm, about 3,000 sccm to about 10,000 sccm, about 3,000 sccm to about 6,000 sccm, or about 1,500 sccm to about 2,000 sccm. In at least some embodiments, the one or more nitrogen containing gases include N₂ and N₂ is flowed into the process chamber at a flow rate of about 0 sccm to about 50,000 sccm, such as about 100 sccm to about 45,000 sccm, about 500 sccm to about 40,000 sccm, about 1,000 sccm to about 35,000 sccm, about 2,000 sccm to about 20,000 sccm, about 3,000 sccm to about 10,000 sccm, about 0 sccm to about 15,000 sccm, or about 500 sccm to about 2,000 sccm. In at least some embodiments, the carrier gas may include argon (Ar), helium (He), or combinations thereof, and is flowed into the process chamber at a flow rate of about 0 sccm to about 30,000 sccm, such as about 1,000 sccm to about 25,000 sccm, about 5,000 sccm to about 20,000 sccm, about 10,000 sccm to about 20,000 sccm, about 15,000 sccm to about 28,000 sccm, or about 15,000 sccm to about 20,000 sccm. In at least some embodiments, a quad chamber having four reactors is used as the process chamber. In such embodiments the flow rate of the gas at each reactor may be about one quarter of the total flow rate. For example, the silicon containing gas may be provided at each reactor at a flow rate of about 0 sccm to about 500 sccm, the one or more nitrogen containing gases may be provided at each reactor at a flow rate of about 0 sccm to about 8,800 sccm, the carrier gas may be provided at each reactor at a flow rate of about 0 sccm to about 7,500 sccm.

For example in at least some embodiments, the first material layer is a SiN layer that is deposited by flowing SiH₄ at a flow rate of about 600 sccm to about 1,900 sccm, NH₃ at a flow rate of about 3,000 sccm to about 8,000 sccm, N₂ at a flow rate of about 0 sccm to about 15,000 sccm, and Ar at a flow rate of about 15,000 sccm to about 28,000 sccm into a process chamber, heating a pedestal to about 530° C. to about 550° C. with a spacing of about 14 mm to about 17 mm, and operating the process chamber at a pressure of about 6 torr to about 7.5 torr, a HFRF power of 1,800 W to about 2,500 W, and a LFRF of about 80 W to about 300 W.

At operation 304, a second material layer is deposited on the first material layer. In at least some embodiments, the second material layer is a SiO layer, such as the second material layer 206. In at least some embodiments, depositing the SiO second material layer includes providing a silicon containing gas, oxygen (O₂), and a carrier gas into a process chamber, heating the pedestal to a temperature of about 250° C. to about 650° C. and operation the process chamber at a pressure of about 0 torr to about 20 torr, a high frequency radio frequency (HFRF) power of about 0 W to about 4,000 W, and a low frequency RF (LFRF) power of about 0 W to about 1,000 W. In at least some embodiments, the second material layer may be doped with N₂ for form an N doped SiO second material layer. Depositing the N doped SiO second material layer may additionally include flowing N₂ into the process chamber.

In at least some embodiments, the pedestal is heated to a temperature of about 400° C. or greater, such as about 450° C. to about 650° C., about 500° C. to about 600° C., about 550° C. to about 600° C., or about 530° C. to about 550° C.. In at least some embodiments, the spacing between the substrate and the showerhead is about 4.5 mm to about 20 mm, such as about 5 mm to about 20 mm, about 5 mm to about 15 mm, about 10 mm to about 20 mm, about 5 mm to about 10 mm, about 15 mm to about 20 mm, or about 4.5 mm to about 6.5 mm. In at least some embodiments, the process chamber is operated at a pressure of about 0 torr to about 20 torr, such as about 1 torr to about 20 torr, about 5 torr to about 20 torr, about 5 torr to about 15 torr, about 5 torr to about 10 torr, or about 3.5 torr to about 5 torr.

In at least some embodiments, the HFRF power may be about 0 W to about 4,000 W, such as about 10 W to about 4,000 W, about 50 W to about 4,000 W, about 100 W to about 4,000 W, about 500 W to about 4,000 W, about 1,000 W to about 4,000 W, about 1,000 W to about 3,500 W, about 1,000 W to about 3,000 W, about 1,500 W to about 3,000 W, about 1,800 W to about 2,500 W, or about 400 W to about 1,200 W. In at least some embodiments, the LFRF power may be about 0 W to about 1,000 W, such as about 10 W to about 1,000 W, about 50 W to about 1,000 W, about 50 W to about 500 W, about 80 W to about 300 W, about 100 W to about 1,000 W, about 500 W to about 1,000 W, about 500 W to about 900 W, about 800 W to about 1,000 W, or about 900 W to about 1,000 W.

In at least some embodiments, the silicon containing gas includes tetraethyl orthosilicate (TEOS) and TEOS is provided into the process chamber in an amount of about 0 milligrams per cubic meter (mg/m³) to about 20,000 mg/m³, such as about 100 mg/m³ to about 20,000 mg/m³, about 500 mg/m³ to about 20,000 mg/m³, about 1,000 mg/m³ to about 20,000 mg/m³, about 5,000 mg/m³ to about 20,000 mg/m³, about 10,000 mg/m³ to about 20,000 mg/m³, or about 15,000 mg/m³ to about 19,000 mg/m³. In at least some embodiments, O₂ is flowed into the process chamber at a flow rate of about 0 standard cubic centimeters per minute (sccm) to about 50,000 sccm, such as about 100 sccm to about 50,000 sccm, about 500 sccm to about 40,000 sccm, about 1,000 sccm to about 40,000 sccm, about 5,000 sccm to about 35,000 sccm, about 10,000 sccm to about 35,000 sccm, about 15,000 sccm to about 30,000 sccm, or about 1,500 sccm to about 2,000 sccm. In at least some embodiments, the carrier gas may include argon (Ar), helium (He), or combinations thereof, and is flowed into the process chamber at a flow rate of about 0 sccm to about 30,000 sccm, such as about 100 sccm to about 30,000 sccm, about 500 sccm to about 25,000 sccm, about 1,000 sccm to about 20,000 sccm, about 5,000 sccm to about 20,000 sccm, about 6,000 sccm to about 15,000 sccm, or about 1,500 sccm to about 2,000 sccm. In at least some embodiments, N₂ may additionally be flowed into the process chamber at a flow rate of about 0 sccm to about 10,000 sccm, such as about 100 sccm to about 8,000 sccm, or about 5,000 sccm to about 1,0000 sccm, to form an N doped SiO second material layer.

For example in at least some embodiments, the second material layer is a SiO layer that is deposited by providing TEOS in an amount of about 15,000 mg/m³ to about 19,000 mg/m³, flowing O₂ at a flow rate of about 15,000 sccm to about 30,000 sccm, and Ar at a flow rate of about 6,000 sccm to about 15,000 sccm in to a process chamber, heating a pedestal to about 400° C. or greater with a spacing of about 4.5 mm to about 6.5 mm, and operating the process chamber at a pressure of about 3.5 torr to about 5 torr, a HFRF power of 400 W to about 12,000 W, and a LFRF of about 500 W to about 900 W.

For example in at least some other embodiments, the second material layer is a N doped SiO layer that is deposited by providing TEOS in an amount of about 15,000 mg/m³ to about 19,000 mg/m³, flowing O₂ at a flow rate of about 15,000 sccm to about 30,000 sccm, N₂ at a flow rate of about 100 sccm to about 1,000 sccm, and Ar at a flow rate of about 6,000 sccm to about 15,000 sccm in to a process chamber, heating a pedestal to about 400° C. or greater with a spacing of about 4.5 mm to about 6.5 mm, and operating the process chamber at a pressure of about 3.5 torr to about 5 torr, a HFRF power of 400 W to about 12,000 W, and a LFRF of about 500 W to about 900 W.

While method 300 describes the second material layer 206 as being deposited over the first material layer 204, in at least some embodiments, the deposition order may be reversed, such that the first material layer 204 (SiN layer) is deposited over the second material layer 206 (SiO layer).

In at least some embodiments, operations 302 and 304 are cyclically repeated to form a plurality of material layer pairs 208, each material layer pair 208 including first material layer 204 and a second material layer 206. Operations 302 and 304 may be repeated any number of times to form an ON stack, such as 2 or more times, 5 or more times, 10 or more times, 50 or more times, 100 or more times, or 500 or more times. In at least some embodiments, operations 302 and 304 are repeated about 100 times to about 200 times to form an ON stack including about 100 to about 200 material layer pairs 208.

At operation 306, the deposited first material layer 204 and second material layer 206 are annealed. In at least some embodiments, annealing the first material layer 204 and second material layer 206 includes heating the first material layer 204 and the second material layer 206 to a temperature of about 700° C. to about 900° C. for about 15 minutes to about 1 hour while flowing N₂. In at least some embodiments, the anneal is a one-step anneal. In other embodiments, the anneal is a multi-step anneal, such as a three-step anneal. In at least some embodiments, annealing the first material layer 204 and second material layer 206 includes heating the first material layer 204 and the second material layer 206 to a temperature of about 650° C. to about 750° C. for about 30 minutes to about 1.5 hours while flowing N₂ in a first step, heating the first material layer 204 and the second material layer 206 to a temperature of about 750° C. to about 850° C. for about 15 minutes to about 45 minutes while flowing N₂ in a second step, and heating the first material layer 204 and the second material layer 206 to a temperature of about 800° C. to about 900° C. for about 15 minutes to about 45 minutes while flowing N₂ in a third step.

FIG. 4 depicts a process flow diagram of a method of forming an ON stack according to some embodiments. Method 400 may be carried out in any suitable process chamber or multiple process chambers. The method 400 generally includes depositing a plurality of first layers on a substrate at operation 402, depositing a plurality of second layers to define a stack at operation 404, and annealing the stack at operation 406.

At operation 402, a plurality of first layers comprising silicon nitride are deposited on a substrate. In at least some embodiments, the plurality of first layers are SiN layers, such as the first material layer 204. In at least some embodiments, depositing the plurality of first layers comprising SiN includes providing a silicon containing gas, one or more nitrogen containing gases, and a carrier gas into a process chamber, heating the pedestal to a temperature of about 400° C. to about 650° C. and operating the process chamber at a pressure of about 0 torr to about 20 torr, a HFRF power of about 0 W to about 4,000 W, and a LFRF power of about 0 W to about 1,000 W. In at least some embodiments, operation 402 may be performed using any of the processing conditions detailed for operation 302 of method 300.

Operation 404 includes, depositing a plurality of second layers comprising silicon oxide on the substrate so that the plurality of second layers are interleaved with the plurality of first layers on top of the substrate to define a stack, such as the ON stack 200. In at least some embodiments, the plurality of second layers are SiO layers, such as the second material layer 206. In at least some embodiments, depositing the plurality of second layers comprising SiO includes providing a silicon containing gas, O₂, and a carrier gas into a process chamber, heating the pedestal to a temperature of about 250° C. to about 650° C. and operation the process chamber at a pressure of about 0 torr to about 20 torr, a HFRF power of about 0 W to about 4,000 W, and a LFRF power of about 0 W to about 1,000 W. In at least some embodiments, operation 404 may be performed using any of the processing conditions detailed for operation 304 of method 300.

Operation 406 includes, annealing the stack. In at least some embodiments, operation 406 may be performed using any of the processing conditions detailed for operation 306 of method 300.

In at least some embodiments, the methods disclosed herein reduce the post anneal Δ bow of the ON stack 200 by modulating the composition and Δ stress of the individual first material layer 204 and second material layer 206. Without being bound by theory, it is believed that the post anneal Δ bow of the ON stack 200 is generally effected by the anneal-induced Δ stress and Δ thickness of the individual first material layer 204 and second material layer 206. Counterintuitively, in at least some embodiments, the Δ bow of the ON stack 200 may be reduced and/or improved when the Δ stress of the individual first material layer 204 and second material layer 206 worsens and/or increases.

In at least some embodiments, the Δ bow of the ON stack 200 may be reduced by depositing a SiN first material layer 204 having a low and/or reduced Si—H content, such as a Si—H content of about 0.35% or less. Si—H and N-bound hydrogen (N—H) are strongly correlated with Δ stress and Δ thickness of SiN layers, such as the first material layer 204. The Si—H and N—H content in a SiN layer may be measured using Infrared (IR) spectroscopy. Si-bound H is more labile than N-bound H with a post-anneal area reduction of about 80% or greater for a Si—H stretch compared to area reduction of about 10% or less for an N—H bend. The extent of H-loss increases with increasing tensile stress of the SiN layer. Without being bound by theory, it is believed that the post anneal changes (e.g. Δ stress and Δ thickness) may arise from local bond reorganization driven by a) H-loss and b) thermal relaxation of bonds. H-loss contributes to thermal relaxation in highly tensile films, thus the film shrinks (−Δ thickness) and bonds become more compressive (−Δ stress) due to new cross-linking. Thermal relaxation contributes to H-loss in highly compressive films, thus the film expands (+Δ thickness), and bonds become relatively tensile (+Δ stress). Between tensile and compressive extremes, a crossover (sign change) occurs around greater than +500 MPa for Δ stress and around less than −500 MPa for Δ thickness. SiN layers exhibit an inverse correlation between as-dep stress and anneal-induced Δ stress/Δ thickness. The lower the bond strength, which decreases as tensile stress increases, the lower the activation energy of hydrogen outgassing. The net effect of hydrogen outgassing (resulting in more cross-linking) and thermal relaxation (relieving strain from Si/SiN lattice mismatch) determines the magnitude and sign of Δ stress and Δ thickness.

In at least some embodiments, for a given as deposited film stress, the Si—H content of a SiN layer may be decreased in a high-spacing/pressure deposition regime. At wider spacings, such as about 14 mm to about 17 mm, the deposition rate drops as the reactive species take longer to reach the wafer allowing more time for cross-linking/condensation of the surface species, thus lowering the residual H content. HFRF power promotes Si—H bond dissociation and lowers residual Si—H content. Higher deposition temperatures promote grain growth with fewer boundaries and defects. In at least some embodiments, a high SiN layer deposition rate of about 5,000 A/min, may be achieved while maintaining a low Δ stress of about 40 to about 80, and a low shrinkage through a balance of depositions conditions including high pressure, substrate spacing, and gas flows/ratios.

In at least some embodiments, a SiN layer, such as the first material layer, may be deposited by flowing SiH₄ at a flow rate of about 1,700 sccm to about 2,000 sccm, NH3 at a flow rate of about 3,200 sccm to about 3,700 sccm, N₂ at a flow rate of about 0 sccm, and Ar at a flow rate of about 23,000 sccm to about 29,000 sccm into a process chamber, heating a pedestal to about 480° C. to about 550° C. with a spacing of about 14 mm to about 17 mm, and operating the process chamber at a pressure of about 6 torr to about 7.5 torr, a HFRF power of 2,000 W to about 2,500 W, and a LFRF of about 40 W to about 80 W. In at least some embodiments, a high temperature deposition method provides a SiN layer having a low Si—H content. The SiN layers deposited at a temperature of about 520° C. or greater show a linier trend between stress and deposition temperature, deposition rate and deposition temperature, and RI and deposition temperature. In at least some embodiments, the N—H content of the SiN layer decreases as the deposition temperature increases. In at least some embodiments, the Si—H content of the SiN layer decreases as the deposition temperature increases up to a temperature of about 520° C. Above a deposition temperature of about 520° C. the Si—H content in the SiN layer becomes stable.

In at least some embodiments, a HFRF deposition method provides a SiN layer having a low Si—H content and a post anneal Δ stress of about 160 MPa or less. The stress and Δ stress of the SiN layer may be tuned by adjusting the ratio of HFRF/LFRF/Ar used during layer deposition. For example, a SiN layer may be deposited by flowing SiH₄ at a flow rate of about 1,700 sccm to about 2,000 sccm, NH3 at a flow rate of about 3,200 sccm to about 5,500 sccm, N₂ at a flow rate of about 0 sccm into a process chamber, and operating the process chamber at a pressure of about 6 torr to about 7.5 torr. In at least some embodiments, SiN layers deposited with a HFRF of about 1400 W or less, a LFRF of about 240 W to about 280W, and an Ar flow rate of about 2,600 sccm have an as deposited stress of about 380 MPa to about 440 MPa and a post anneal Δ stress of about 380 MPa to about 560 MPa. In at least some other embodiments, SiN layers deposited with a HFRF of about 1,500 W to about 2,300, a LFRF of about 0 W to about 230 W, and a Ar flow rate of about 0 sccm to about 4,000 sccm have an as deposited stress of about 380 MPa to about 440 MPa and a post anneal Δ stress of about 160 MPa or less. SiN layers deposited with a HFRF of about 1,800 W to about 2,300, a LFRF of about 0 W to about 100 W, and an Ar flow rate of about 0 sccm to about 2,600 sccm have an as deposited stress of about 380 MPa to about 440 MPa and a post anneal Δ stress of about 20 MPa to about 50MPa. The Si—H content of SiN layers having similar stresses and RIs may decrease with the deposition HFRF/LFRF ratio while the N—H content remains relatively the same, resulting in a low Δ stress. The N—H content may be reduced by replacing the LFRF with additional Ar, without changing the Si—H content.

Embodiments of the present disclosure relate to apparatuses and methods of manufacturing layer stacks of ON layers that reduce or prevent anneal-induced structural changes of an ON stack. In some embodiments, the methods generally include depositing a first material including SiN and having a low Si—H content, depositing a second material layer including SiO and having a nitrogen content of about 0.01% to about 1.5%, repeating the deposition of the first and second material layers to for a stack, and annealing the deposited first and second material layers. In at least some embodiments, a high SiN layer deposition rate of about 5,000 A/min, may be achieved while maintaining a low post thermal anneal Δ stress of about 40 MPa to about 60 MPa, a low shrinkage, an as deposited stress of about 400 Mpa or less, and a RI of about 1.9 or greater when measured at 248 nm, through a balance of depositions conditions including high pressure, substrate spacing, and gas flows/ratios. In at least some embodiments, a high temperature deposition method provides a SiN layer having a low Si—H content. In at least some embodiments, a high frequency Radio Frequency (HFRF) deposition method provides a SiN layer having a low Si—H content and a post anneal Δ stress of about 20 MPa to about 50 MPa. In at least some embodiments, the methods disclosed herein provide a SiO layer having a nitrogen content of about 0.01% to about 1.5%. In at least some embodiments, the methods disclosed herein provide an ON stack having a post anneal Δ bow of about −10 μm to about 20 μm.

Unless stated otherwise, all chemical bond related content disclosed above, such as the percent Si—H, N—H, and/or Si—N present in a material layer, was determined via peak height of Fourier Transform Infrared Spectroscopy. All elemental concentrations disclosed above, such as the percent nitrogen, oxygen, and/or hydrogen present in a material layer, were determined via secondary ion mass spectrometry. All RIs were measured at 248 nm.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present disclosure, other and further embodiments of the disclosure may be devised without departing from the basic scope thereof, and the scope thereof is determined by the claims that follow.

1. A method of forming an oxide/nitride (ON) stack, comprising:
depositing a first material layer comprising silicon nitride (SiN) and having a silicon-hydrogen bond (Si—H) content of about 0.35% or less;
depositing a second material layer onto the first material layer, the second material layer comprising silicon oxide (SiO) and having a nitrogen content of about 0.01% to about 1.5%; and
annealing the first material layer and the second material layer.

2. The method of claim 1, wherein the first material layer has an as deposited tensile stress greater than about 300 MPa and the second material layer has an as deposited compressive stress of greater than about −300 MPa.

3. The method of claim 1, wherein the first material layer has a post anneal delta (Δ) stress of about −15 MPa to about 80 MPa.

4. The method of claim 1, wherein the second material layer has a post anneal Δ stress of about 20 MPa to about 50 MPa.

5. The method of claim 1, wherein the ON stack has a post anneal Δ bow of about −5 μm to about 50 μm.

6. The method of claim 1, wherein the ON stack has a post anneal Δ bow of about −10 μm to about 20 μm.

7. The method of claim 1, wherein depositing the first material layer comprises operating a process chamber at a high frequency radio frequency (HFRF) power of about 1,800 W to about 2,500 W, and a low frequency RF (LFRF) power of about 0 W to about 300 W.

8. The method of claim 1, wherein depositing the second material layer comprises doping the second material layer with nitrogen (N₂).

9. The method of claim 1, wherein the first material layer has a thickness of about 200 A to about 300 A.

10. The method of claim 1, wherein the second material layer has a thickness of about 100 A to about 200 A.

11. The method of claim 1, wherein depositing the first material layer and depositing the second material layer are repeated about 100 times to about 200 times to form a stack comprising about 100 to about 200 material layer pairs.

12. A method of forming an ON stack, comprising:
depositing a first material layer comprising silicon nitride (SiN), the deposition comprising:
providing a silicon containing gas, one or more nitrogen containing gases, and a carrier gas into a process chamber; and
operating the process chamber at a high frequency radio frequency (HFRF) power of about 1,500 W to about 2,500 and a low frequency RF (LFRF) power of about 0 W to about 1,000 W;
depositing a second material layer onto the first material layer, the second material layer comprising silicon oxide (SiO);
repeating depositing the first material layer and depositing the second material layer one or more times to form the ON stack; and
annealing the ON stack.

13. The method of claim 12, wherein the HFRF power is about 1,800 W to about 2,300 W.

14. The method of claim 12, wherein the LFRF power is about 80 W to about 300 W.

15. The method of claim 12, wherein depositing the first material layer further comprises heating a pedestal of the process chamber to a temperature of about 400° C. to about 650° C.

16. The method of claim 12, wherein the first material layer has a post anneal Δ stress of about 20 MPa to about 50 MPa.

17. A method of forming an ON stack, comprising:
depositing a first material layer comprising silicon nitride;
depositing a second material layer onto the first material layer, the second material layer comprising silicon oxide (SiO), the deposition comprising:
providing a silicon containing gas, oxygen (O₂), nitrogen (N₂), and a carrier gas into a process chamber; and
operating the process chamber at a high frequency radio frequency (HFRF) power of about 0 W to about 4,000 W and a low frequency RF (LFRF) power of about 0 W to about 1,000 W;
repeating depositing the first material layer and depositing the second material layer one or more times to form the ON stack; and
annealing the ON stack.

18. The method of claim 17, wherein N₂ is provided into to process chamber at a flow rate of about 100 sccm to about 1,000 sccm.

19. The method of claim 17, wherein the ON stack has a post anneal Δ bow of about 12 μm to about 20 μm.

20. The method of claim 17, wherein annealing the first material layer and the second material layer comprises heating the first material layer and the second material layer to a temperature of about 700° C. to about 900° C. for about 15 minutes to about 1 hour.
